(19) United States
(12) Patent Application Publication
(10) Pub. No.: US 2019/0051596 A1
(43) Pub. Date: Feb. 14, 2019

(54) METHOD OF INCREASING EMBEDDED 3D METAL-INSULATOR-METAL (MIM) CAPACITOR CAPACITANCE DENSITY FOR WAFER LEVEL PACKAGING

(71) Applicant: APPLIED MATERIALS, INC., Santa Clara, CA (US)

(72) Inventors: Peng Suo, Singapore (SG); Yu Gu, Singapore (SG); Guan Huei See, Singapore (SG); Arvind Sundarajan, Singapore (SG)

(21) Appl. No.: 15/673,478

(22) Filed: Aug. 10, 2017

(51) Int. Cl. H01L 23/522; H01L 21/768; H01L 21/027; H01L 21/02; H01L 21/283; H01L 23/528; H01L 21/3105; H01L 49/02

(52) U.S. Cl. CPC H01L 23/5223; H01L 21/76877; H01L 23/5226; H01L 21/76816; H01L 21/0273; H01L 23/5329; H01L 21/283; H01L 23/5283; H01L 21/31058; H01L 28/91; H01L 21/02118

(57) ABSTRACT

Methods of processing a substrate include providing a substrate having a polymer dielectric layer and a metal layer formed atop the polymer dielectric layer; depositing a plurality of polymer layers atop the substrate; patterning the plurality of polymer layers to form at least one via that extends from a top surface of an uppermost polymer layer to a top surface of the metal layer; and forming a three-dimensional metal-insulator-metal (3D MIM) capacitance stack in the at least one via and over a portion of the metal layer and the plurality of polymer layers.

### FIELD

Embodiments of the present disclosure generally relate to three-dimensional metal-insulator-metal (“3D MIM”) capacitors in integrated circuits.

### BACKGROUND

Capacitors are one component in semiconductor devices that can occupy considerable area on a semiconductor die depending on the size of the capacitor and/or the number of capacitors on the die. One example of a capacitor used in a semiconductor memory device is a metal-insulator-metal (MIM) capacitor. A traditional MIM capacitor is two-dimensional (2D). A 2D MIM capacitor has two facing metal plates which are planar and substantially parallel to each other and to the substrate. One method of increasing the capacitance of a MIM capacitor is to increase the sizes of the metal plates. However, increasing the sizes of the metal plates will consume more surface area of the substrate. Accordingly, a need exists to reduce the surface area on the substrate occupied by a capacitor without sacrificing the capacitance.

Accordingly, the inventors have developed an improved 3-dimensional metal-insulator-metal (3D MIM) capacitor and method of forming a 3D MIM capacitor.

### SUMMARY

In some embodiments, a method of processing a substrate comprises providing a substrate having a polymer dielectric layer and a metal layer formed atop the polymer dielectric layer; depositing a plurality of polymer layers atop the substrate; patterning the plurality of polymer layers to form at least one via that extends from a top surface of an uppermost polymer layer to a top surface of the metal layer; and forming a three-dimensional metal-insulator-metal (3D MIM) capacitance stack in the at least one via and over a portion of the metal layer and the plurality of polymer layers.

In some embodiments, a method of processing a substrate includes providing a substrate having a polymer dielectric layer and a metal layer formed atop the polymer dielectric layer; depositing a first polymer layer atop the substrate; patterning the first polymer layer to form a first opening to a top surface of the metal layer; curing the first polymer layer; forming a first contact within the first opening to the top surface of the metal layer; forming a first metal pad over the first contact; depositing a second polymer layer atop the substrate; patterning the second polymer layer to form a second opening to the top surface of the first metal pad; curing the second polymer layer; forming a second contact within the second opening to a top surface of the first metal pad; forming a second metal pad over the second contact; depositing a third polymer layer atop the substrate; patterning the third polymer layer to form a third opening to the top surface of the second metal pad; curing the third polymer layer; patterning the first, second, and third polymer layers to form a plurality of vias to the top surface of the metal layer; and forming a three-dimensional metal-insulator-metal (3D MIM) capacitance stack in the plurality of vias and over a portion of the metal layer, the first polymer layer, the second polymer layer, and the third polymer layer.

In some embodiments, a semiconductor device comprises at least two polymer layers over a metal layer on a substrate; and a three-dimensional metal-insulator-metal (3D MIM) capacitance stack formed in at least one via, wherein the at least one via extends from a top surface of an uppermost polymer layer to the metal layer, wherein an aspect ratio of at least one of the at least one via is approximately 2:1 or greater.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are not to be considered limiting of scope, for the disclosure may admit to other equally effective embodiments.

FIG. 1 depicts a flow chart of a method for processing a substrate in accordance with some embodiments of the present principles.

FIGS. 2A-2F depict the stages of processing a substrate in accordance with some embodiments of the present principles.

FIG. 3 depicts a flow chart of a method for processing a substrate in accordance with some embodiments of the present principles.

FIG. 4 depicts an embodiment of a 3-dimensional metal-insulator-metal capacitor in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Methods for processing a substrate to form an enhanced three-dimensional metal-insulator-metal (3D MIM) capacitor are disclosed. The inventive methods advantageously facilitate an improved 3D MIM capacitor with increased capacitance density and reduced size. The methods can be used to beneficially form the 3D MIM capacitor with wafer level packaging processes instead of back-end-of-line (BEOL) processes, reducing costs and usage of semiconductor chip real estate. The advantageous high capacitance density is achieved by creating vias for the 3D MIM capacitor that have high aspect ratios of approximately 2:1 or greater. The high aspect ratios of the vias are obtained by incorporating multiple layers of polymer into the formation of the 3D MIM capacitor.

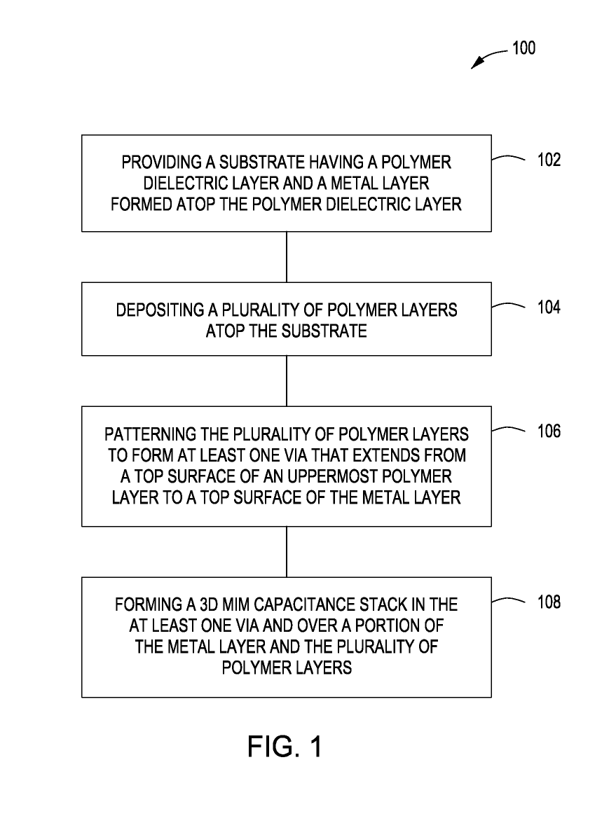

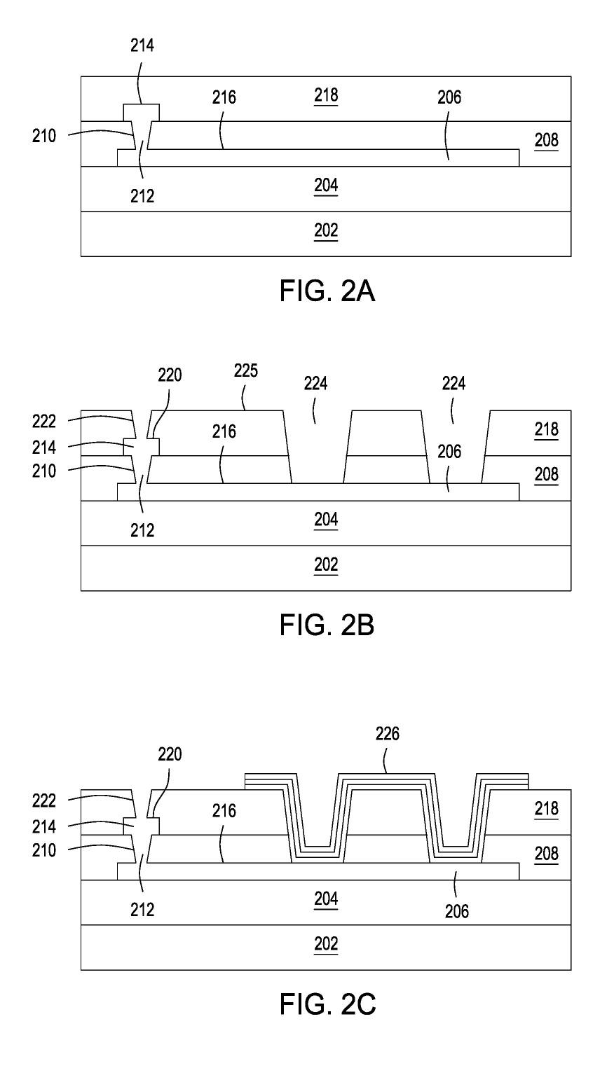

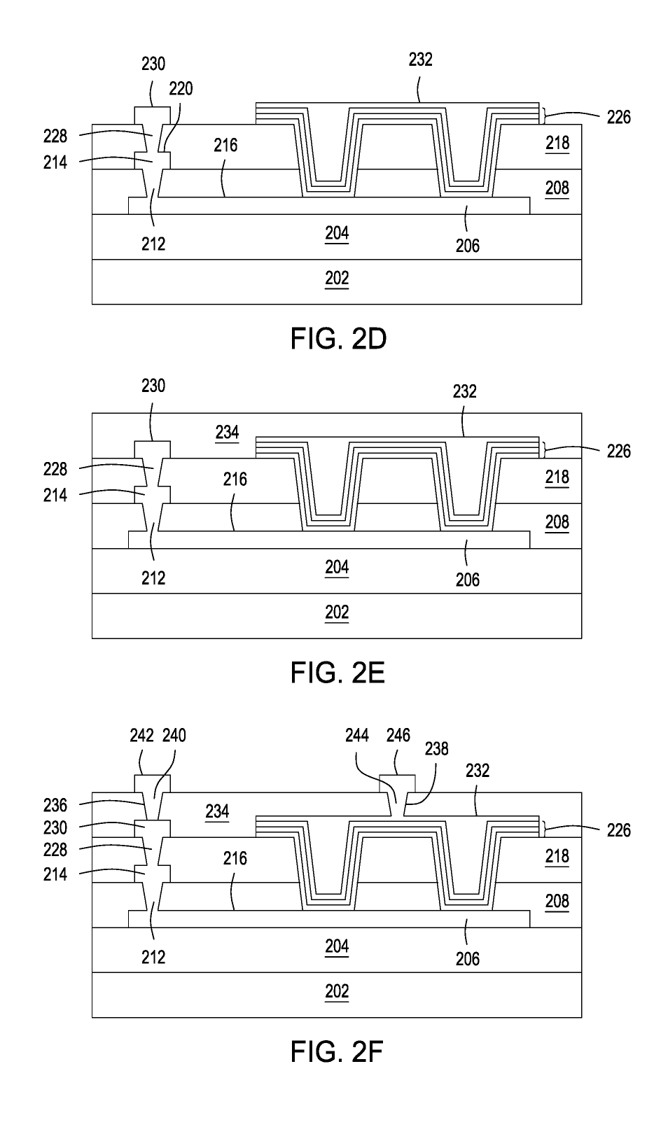

FIG. 1 depicts a flow chart of a method 100 for processing a substrate in accordance with some embodiments of the present principles. The method 100 is described herein with respect to the structure depicted in FIGS. 2A-2F. The method 100 of the present principles may be performed in a single process chamber capable of performing both etching and deposition. Such a suitable process chamber may be a standalone process chamber, or part of a cluster tool. Alternatively, the inventive methods disclosed herein may be performed in separate chambers that also may be standalone or part of a cluster tool.

The method 100 generally begins at 102, as depicted in FIG. 2A, by providing a substrate 202 having a polymer dielectric layer 204 and a metal layer 206 formed atop the polymer dielectric layer 204. The substrate 202 may be any suitable substrate material used in semiconductor manufacturing processes. For example, the substrate 202 may be silicon, glass, ceramic, dielectric, or epoxy mold compound. The polymer dielectric layer 204 may comprise any suitable polymer dielectric material such as polyimide, polybenzoxazole, or benzocyclobutene (BCB), or the like. The metal layer 206 may comprise any suitable conductive material used to form a metal interconnect such as copper or aluminum, or the like. The metal layer 206 is a redistribution layer (i.e., a layer to redirect connectivity to the pad) provided over the polymer dielectric layer 204. In some embodiments, the metal layer 206 may be formed using a plating process or deposition process, such as a physical vapor deposition process, used in a semiconductor manufacturing processes.

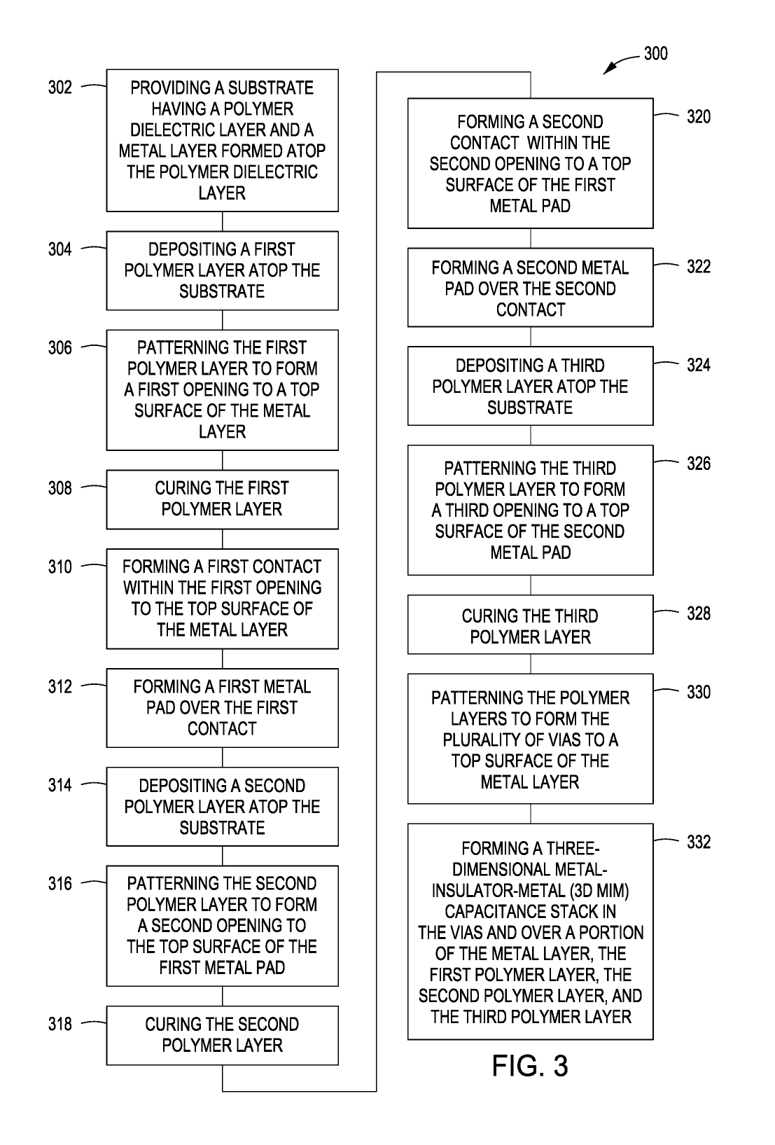

Next, at 104, a plurality of polymer layers are deposited atop the substrate. In FIG. 2A, some embodiment with two polymer layers is shown. A first polymer layer 208 and a second polymer layer 218. Some embodiments may have more than two polymer layers (see FIGS. 3 & 4 below as an example of some embodiments with three polymer layers). In some embodiments, the first polymer layer 208 is spin-coated over the substrate 202. The first polymer layer 208 may be deposited using any suitable spin-coating process or lithographic process. In some embodiments, the first polymer layer 208 is a polybenzoxazole (PBO) layer, a polyimide layer, a benzocyclobutene (BCB) layer, an epoxy layer, or a photo-sensitive material layer. Typically, a first opening 210 is formed from a top surface of the first polymer layer 208 to the metal layer 206. A conductive material is then deposited in the first opening 210 to form a first contact 212 to a top surface of the metal layer 206. A first metal pad 214 is then formed over the first contact 212. The second polymer layer 218 is then deposited on the substrate 202. In some embodiments, the second polymer layer 218 layer is spin-coated over the substrate 202. The second polymer layer 218 may be deposited using any suitable spin-coating process or lithographic process. In some embodiments, the second polymer layer 218 is a polybenzoxazole (PBO) layer, a polyimide layer, a benzocyclobutene (BCB) layer, an epoxy layer, or a photo-sensitive material layer.

Next, at 106, and as depicted in FIG. 2B, the second polymer layer 218 is patterned to form an opening 222 and vias 224. In some embodiments, the second polymer layer 218 may have only one via. The opening 222 is formed to a top surface 220 of the first metal pad 214. In some embodiments, the patterning process may be any suitable lithographic process for forming the opening 222 in the second polymer layer 218. In some embodiments, the patterning process includes forming a photoresist layer on the second polymer layer 218 and using a dry etch process to form vias 224. The vias 224 extend from a top surface 225 of an uppermost polymer layer (the second polymer layer 218 in a two polymer layer embodiment) to a top surface 216 of the metal layer 206.

The vias 224 propagate through a plurality of polymer layers (in the two layer example—the first polymer layer 208 and the second polymer layer 218). The propagation of the vias 224 through multiple layers allows the aspect ratio of the vias 224 to be approximately 2:1 or greater. The higher the number of polymer layers, the greater the achievable aspect ratio. Although the example depicted in FIGS. 2A-2F has two polymer layers, the methods of the present principles are not limited to two polymer layers. An increased aspect ratio allows the subsequent 3D MIM capacitance stack 226 formed in the vias 224 to have increased capacitance density while maintaining a similar size compared to lower aspect ratio capacitors. The higher sidewalls of the vias 224 permit more of the 3D MIM capacitance stack 226 to be formed for a given area, increasing the capacitance density.

Factors limiting high numbers of polymer layers (e.g., >5 layers of polymer) may be overcome as technologies improve. A deposited polymer layer is typically cured before further processing. The more polymer layers, the more time spent for deposition and curing of the polymer layers. Deposition of a polymer layer over existing structures or defects on the substrate may introduce a topography to the top surface of the uppermost polymer layer (rather than the uppermost polymer layer being planar). The topography may have greater variances as the number of polymer layers is increased. In addition, etching time increases exponentially as the number of polymer layers is increased. A point of diminishing returns may be reached after a given number of polymer layers (manufacturing time and cost versus capacitance density or value to a process). Planarization processes may be introduced after deposition of one or more polymer layers in some embodiments of the present principles to alleviate topography issues.

In some embodiments, the polymer layers may be etched using a patterned photoresist layer (not shown). For example, a photoresist material can be deposited on the substrate 202 and then exposed to light filtered by a reticle, such as a glass plate that is patterned with exemplary feature geometries that block light from propagating through the reticle. After passing through the reticle, the light contacts the surface of the photoresist material and changes the chemical composition of the photoresist material such that a developer can remove a portion of the photoresist material. In the case of positive photoresist materials, the exposed regions are removed, and in the case of negative photoresist materials, the unexposed regions are removed. The photoresist layer may comprise any photoresist materials suitable to provide a template to facilitate etching the polymer layers from within the vias 224.

For example, in some embodiments, the photoresist material may be a positive or negative photoresist and/or a DUV or EUV (deep ultraviolet or extreme ultraviolet) photoresist and may comprise one or more of polymers, organic compounds (e.g., comprising carbon, hydrogen and oxygen), an amorphous carbon, such as Advanced Patterning Film (APF), available from Applied Materials, Inc., located in Santa Clara, Calif., a tri-layer resist (e.g., a photoresist layer, a Si-rich anti-reflective coating (ARC) layer, and a carbon-rich ARC, or bottom ARC (BARC) layer), a spin-on hardmask (SOH), or the like. Thereafter, the polymer layers are etched to remove the material from the areas that are no longer protected by the photoresist material. The photoresist material is then stripped from the substrate 202.

Next at 108, and as depicted in FIG. 2C, a 3D MIM capacitance stack 226 is formed in the vias 224 and over a portion of a plurality of polymer layers (such as, for example, the first polymer layer 208 and the second polymer layer 218 in the two polymer layer example shown in FIG. 2C) and the metal layer 206. The 3D MIM capacitance stack 226 may be constructed, for example, by processes provided in U.S. patent application Ser. No. 15/288,594, by Guan Huei See, et al., published on Apr. 13, 2017 as 2017-0104056, and entitled Structure and Method of Fabricating Three-Dimensional (3D) Metal-Insulator-Metal (MIM) Capacitor and Resistor in Semi-Additive Plating Metal Wiring.

A conductive material is deposited into the first opening 210 to form a second contact 228 that is electrically connected to a top surface 220 of the first metal pad 214 shown in FIG. 2D. A second metal pad 230 is formed over the second contact 228. A conductive layer 232 is also formed over the 3D MIM capacitance stack 226. A third polymer layer 234 is then deposited over the substrate 202. An opening 236 is formed in the third polymer layer 234 to form a third contact 240 that is electrically connected with the second metal pad 230. A third metal pad 242 is then formed on the third contact 240 to provide an electrical connection with the metal layer 206 that is also in electrical contact with a bottom of the 3D MIM capacitance stack 226. An opening 238 is formed in the third polymer layer 234 to form a fourth contact 244. A fourth metal pad 246 is then formed on the fourth contact 244 to provide an electrical connection to the conductive layer 232 that is also in electrical contact with a top surface of the 3D MIM capacitance stack 226. The metal pads, contacts, or conductive layers used in some embodiments may be deposited using any suitable deposition process, for example an electroplating process.

As discussed previously, the high aspect ratio of the vias 224 translates into a high aspect ratio for the 3D MIM capacitance stack, advantageously increasing the capacitance density. Aspect ratios of greater than approximately 2:1 can be achieved with the processes of the present principles. In some embodiments, the aspect ratio can be approximately 2:1 to approximately 5:1. Some embodiments have an aspect ratio of approximately 3:1.

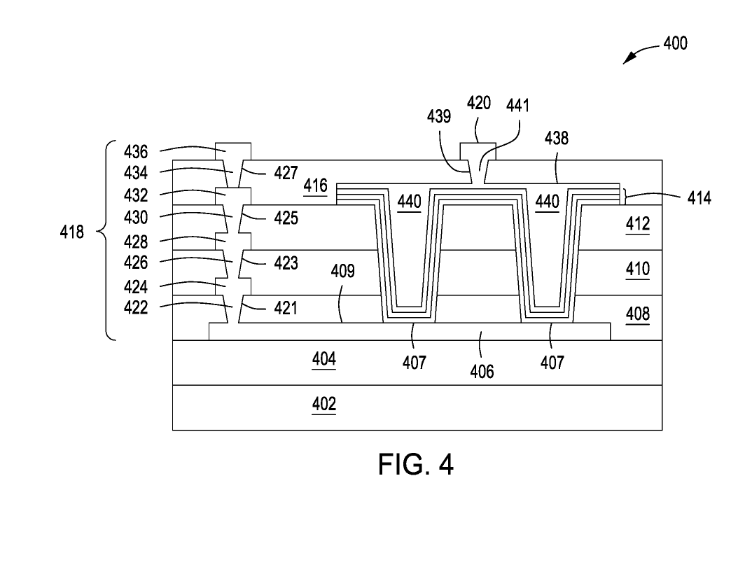

FIG. 3 depicts a flow chart of a method 300 for processing a substrate in accordance with some embodiments of the present principles. The method 300 is described herein with respect to the structure depicted in FIG. 4. The method 300 of the present principles may be performed in a single process chamber capable of performing both etching and deposition. Such a suitable process chamber may be a standalone process chamber, or part of a cluster tool. Alternatively, the inventive methods disclosed herein may be performed in separate chambers that also may be standalone or part of a cluster tool.

The method 300 is a process for constructing a 3D MIM capacitor 400 depicted in FIG. 4 for some embodiments with three polymer layers. The method 300 starts, at 302, by providing a substrate 402 having a polymer dielectric layer 404 and a metal layer 406 formed atop the polymer dielectric layer 404. The metal layer 406 provides an embedded electrical contact for a bottom surface 407 of a 3D MIM capacitance stack 414 that is formed in subsequent processes. At 304, a first polymer layer 408 is deposited atop the substrate 402. The first polymer layer 408 overlays at least a portion of the metal layer 406 and the polymer dielectric layer 404. At 306, the first polymer layer 408 is patterned to form a first opening 421 to a top surface 409 of the metal layer 406 using a lithography method. The first opening 421 allows an electrical connection to be made to the metal layer 406 which is in electrical contact with the bottom surface 407 of the 3D MIM capacitance stack 414.

At 308, the first polymer layer 408 is cured to remove any solvents and to establish good crosslinking of the molecules inside of the first polymer layer 408. The curing process insures that the first polymer layer 408 is strong enough to be reliable and to protect the semiconductor package from mechanical and electrical stresses. The curing process generates a certain amount of shrinkage of the polymer volume, typically shrinking by as much as approximately 15% to approximately 30%. The shrinkage of the polymer during the curing process may also limit the total number of polymer layers that can be used in the processes of the present principles due to possible warpage of the substrate caused by the polymer shrinkage. Improvements in reducing polymer shrinkage during the curing process will also permit increases in the number of polymer layers that can be used for 3D MIM capacitors constructed according to the present principles. The more polymer layers used, the greater the aspect ratio for a given 3D MIM capacitor and the greater the capacitance density for the given 3D MIM capacitor.

At 310, a first contact 422 is formed within the first opening 421 to the top surface 409 of the metal layer 406. The first contact 422 is a conductive material that is used to extend the electrical connection formed by the metal layer 406 to a top surface of the first polymer layer 408. At 312, a first metal pad 424 is formed over the first contact 422 to permit subsequent electrical contact with the metal layer 406. At 314, a second polymer layer 410 is deposited atop the substrate 402. The second polymer layer 410 overlays at least a portion of the first polymer layer 408 and the first metal pad 424. At 316, the second polymer layer 410 is patterned to form a second opening 423 to a top surface of the first metal pad 424. At 318, the second polymer layer 410 is cured to remove solvents and to establish good crosslinking of the molecules inside of the second polymer layer 410. At 320, a second contact 426 is formed within the second opening 423 to a top surface of the first metal pad 424. The second contact 426 is a conductive material that is used to extend the electrical connection formed by the metal layer 406 to a top surface of the second polymer layer 410.

At 322, a second metal pad 428 is formed over the second contact 426 to permit subsequent electrical contact with the metal layer 406. At 324, a third polymer layer 412 is deposited atop the substrate 402. The third polymer layer 412 overlays at least a portion of the second polymer layer 410 and the second metal pad 428. At 326, the third polymer layer 412 is patterned to form a third opening 425 to a top surface of the second metal pad 428. At 328, the third polymer layer 412 is cured to remove solvents and to establish good crosslinking of the molecules inside of the third polymer layer 412. A third contact 430 may be formed within the third opening 425 to a top surface of the second metal pad 428. The third contact 430 is a conductive material that is used to extend the electrical connection formed by the metal layer 406 to a top surface of the third polymer layer 412. A third metal pad 432 may formed over the third contact 430 to permit subsequent electrical contact with the metal layer 406.

At 330, the first, second, and third polymer layers 408, 410, and 412 are patterned to form a plurality of vias 440 to the top surface 409 of the metal layer 406. The plurality of vias 440 can be patterned using, for example, a photoresist process and a dry etching process. The plurality of vias 440 expose a portion of the metal layer 406 so the metal layer 406 can function as an embedded electrical connection. At 332, a 3D MIM capacitance stack 414 is formed in the plurality of vias 440, including a portion of the metal layer 406 at a bottom of the plurality of vias 440, the first polymer layer 408, the second polymer layer 410, and the third polymer layer 412. The 3D MIM capacitance stack 414 will have an aspect ratio of approximately 3:1, substantially increasing the capacitance density. The 3D MIM capacitance stack 414 may have a conductive layer 438 formed on a top surface of the 3D MIM capacitance stack 414.

A fourth polymer layer 416 may be deposited on the substrate 402 to electrically isolate the 3D MIM capacitance stack 414. A fourth opening 427 and a fifth opening 439 may be formed in the fourth polymer layer 416. A fourth contact 434 may be formed within the fourth opening 427 to a top surface of the third metal pad 432. The fourth contact 434 is a conductive material that is used to extend the electrical connection formed by the metal layer 406 to a top surface of the fourth polymer layer 416. A fourth metal pad 436 may be formed over the fourth contact 434 to permit subsequent electrical contact with the metal layer 406. The series of contacts and metal pads form a conductive path 418 from an upper surface to the embedded bottom contact of the 3D MIM capacitance stack 414.

A fifth contact 441 may be formed within the fifth opening 439 to a top surface of the conductive layer 438 that is electrically connected with a top surface of the 3D MIM capacitance stack 414. The fifth contact 441 is a conductive material that is used to extend the electrical connection with the conductive layer 438 to a top surface of the fourth polymer layer 416. A fifth metal pad 420 may be formed over the fifth contact 441 to permit subsequent electrical contact with the conductive layer 438.

The example illustrations are not meant to be limiting. Although some embodiments may use three polymer layers for the 3D MIM capacitor, as discussed previously, some embodiments may have more or less than three polymer layers. Advances in etching rates and reduction in polymer shrinkage during curing along with employment of planarization processes to eliminate topography deviations of the polymer layer surface may produce 3D MIM capacitors with an unlimited number of polymer layers and aspect ratios of substantially greater than 3:1.

While the foregoing is directed to embodiments of the present disclosure, other and further embodiments of the disclosure may be devised without departing from the basic scope thereof.

1. A method of processing a substrate, comprising:
providing a substrate having a polymer dielectric layer and a metal layer formed atop the polymer dielectric layer;
depositing a plurality of polymer layers atop the substrate;
patterning the plurality of polymer layers to form at least one via that extends from a top surface of an uppermost polymer layer to a top surface of the metal layer; and
forming a three-dimensional metal-insulator-metal (3D MIM) capacitance stack in the at least one via and over a portion of the metal layer and the plurality of polymer layers.

2. The method of claim 1, further comprising:
forming at least one of the at least one via with an aspect ratio of approximately 2:1 or greater.

3. The method of claim 1, further comprising:
forming a first electrical connection with the top surface of the metal layer on a top surface of an uppermost polymer layer; and
forming a second electrical connection with a top surface of the 3D MIM capacitance stack.

4. The method of claim 3, wherein the first electrical connection and the second electrical connection are copper or aluminum.

5. The method of claim 1, further comprising:
patterning the plurality of polymer layers by forming a photoresist layer on the uppermost polymer layer and using a dry etch process to create the at least one via.

6. The method of claim 1, wherein the metal layer is copper or aluminum.

7. The method of claim 1, wherein the polymer dielectric layer is polyimide, polybenzoxazole, or benzocyclobutene (BCB).

8. The method of claim 1, wherein at least one of the plurality of polymer layers is a polybenzoxazole (PBO) layer, a polyimide layer, a benzocyclobutene (BCB) layer, an epoxy layer, or a photo-sensitive material layer.

9. A method of processing a substrate, comprising:
providing a substrate having a polymer dielectric layer and a metal layer formed atop the polymer dielectric layer;
depositing a first polymer layer atop the substrate;
patterning the first polymer layer to form a first opening to a top surface of the metal layer;
curing the first polymer layer;
forming a first contact within the first opening to the top surface of the metal layer;
forming a first metal pad over the first contact;
depositing a second polymer layer atop the substrate;
patterning the second polymer layer to form a second opening to the top surface of the first metal pad;
curing the second polymer layer;
forming a second contact within the second opening to a top surface of the first metal pad;
forming a second metal pad over the second contact;
depositing a third polymer layer atop the substrate;
patterning the third polymer layer to form a third opening to the top surface of the second metal pad;
curing the third polymer layer;
patterning the first, second, and third polymers layer to form a plurality of vias to the top surface of the metal layer; and
forming a three-dimensional metal-insulator-metal (3D MIM) capacitance stack in the plurality of vias and over a portion of the metal layer, the first polymer layer, the second polymer layer, and the third polymer layer.

10. The method of claim 9, further comprising:
patterning the first, second, and third polymer layers by forming a photoresist layer on the third polymer layer and using a dry etch process to create the plurality of vias.

11. The method of claim 9, wherein the substrate is silicon, glass, ceramic, dielectric, or epoxy mold compound.

12. The method of claim 9, wherein the first metal pad and the second metal pad are copper or aluminum.

13. The method of claim 9, wherein the metal layer is copper or aluminum.

14. The method of claim 9, wherein the polymer dielectric layer is polyimide, polybenzoxazole, or benzocyclobutene (BCB).

15. The method of claim 9, wherein the first polymer layer, the second polymer layer, or the third polymer layer is a polybenzoxazole (PBO) layer, a polyimide layer, a benzocyclobutene (BCB) layer, an epoxy layer, or a photo-sensitive material layer.

16. A semiconductor device, comprising:
at least two polymer layers over a metal layer on a substrate; and
a three-dimensional metal-insulator-metal (3D MIM) capacitance stack formed in at least one via, wherein the at least one via extends from a top surface of an uppermost polymer layer to the metal layer, wherein an aspect ratio of at least one of the at least one via is approximately 2:1 or greater.

17. The semiconductor device of claim 16, further comprising:
a first metal pad on the uppermost polymer layer that is in electrical contact with the metal layer; and
a second metal pad on that is in electrical contact with a top surface of the 3D MIM capacitance stack.

18. The semiconductor device of claim 17, wherein the first metal pad and the second metal pad are copper or aluminum.

19. The semiconductor device of claim 16, wherein at least one of the at least two polymer layers is a polybenzoxazole (PBO) layer, a polyimide layer, a benzocyclobutene (BCB) layer, an epoxy layer, or a photo-sensitive material layer.

20. The semiconductor device of claim 16, wherein the substrate is silicon, glass, ceramic, dielectric or epoxy mold compound.
